(19) United States
(12) Patent Application Publication
(10) Pub. No.: US 2020/0051778 A1
(43) Pub. Date: Feb. 13, 2020

(54) MICROTOME, SCANNING ELECTRON MICROSCOPE AND METHOD FOR PREPARING THIN SLICES FROM A SAMPLE AND METHOD FOR ANALYSING THIN SLICES PRODUCED FROM A SAMPLE IN A SCANNING ELECTRON MICROSCOPE AND USE OF A MAGNETIC TAPE FOR THE PURPOSE OF DEPOSITING AND TRANSPORTING OF THIN SLICES OF SAMPLES IN THE FIELD OF SCANNING ELECTRON MICROSCOPY

(71) Applicant: RUPRECHT-KARLS-UNIVERSITAT HEIDELBERG, Heidelberg (DE)

(72) Inventor: Heinrich HORSTMANN, Plankstadt (DE)

(21) Appl. No.: 16/339,848

(22) PCT Filed: Oct. 20, 2017
(86) PCT No.: PCT/EP2017/076914

§ 371 Date: Apr. 5, 2019

(30) Foreign Application Priority Data
Oct. 21, 2016 (DE) 10 2016 120 113.8

(51) Int. Cl. H01J 37/28; G01N 1/06

(52) U.S. Cl. CPC H01J 37/28; G01N 2001/002; G01N 1/06

(57) ABSTRACT

Microtome (1), comprising a blade (2) for cutting thin slices from a sample, a sample holder (3) for guiding the sample onto the blade (2), and a means (4) for receiving the thin slices, the means (4) being a tape (5) on which the thin slices are deposited, the tape (5) being unwound from a first holder (24) and wound up together with the thin slices onto a second holder (7), and scanning electron microscope having an electron detector, comprising a chamber and a sample supply means (12), the sample supply means (12) being formed to supply the thin slices located on the wound-up tape (5) to the electron detector and use of a magnetic tape (5) known from digital storage technology for the purpose of depositing and transporting of thin slices of samples in the above described microtome (1) and scanning electron microscope.

Microtome, scanning electron microscope and method for preparing thin slices from a sample and method for analysing thin slices produced from a sample in a scanning electron microscope and use of a magnetic tape for the purpose of depositing and transporting of thin slices of samples in the field of scanning electron microscopy

The invention relates to a microtome, comprising a blade for cutting thin slices from a sample, a sample holder for guiding the sample onto the blade, and a means for receiving the thin slices, the device being a tape on which the thin slices are deposited, and to a method for preparing thin slices using a microtome. The invention further relates to a scanning electron microscope having an electron detector, comprising a chamber and a sample supply means, and to a method for analysing the thin slices which are arranged on a tape. The invention further relates to the use of a magnetic tape known from digital storage technology for the purpose of depositing and transporting of thin slices of samples in the described microtome and scanning electron microscope of the current invention.

For analysing samples in a scanning electron microscope, it is known to prepare a sample in such a way that thin slices can be prepared therefrom using a microtome. For example, this may take place in that the sample is treated with an epoxy resin in such a way that said sample solidifies. Subsequently, thin slices can be produced from the solidified sample using a microtome.

A microtome comprises a knife having a blade, for example made of a diamond, which is guided along on the sample in such a way that thin slices are cut off from the sample. In this context, it is known to move the knife either in translation or in a combination of a translational and an oscillatory movement. In the case of the combination of translational and oscillatory movement, a thin slice can be prevented from adhering to the blade.

A thin slice for analysing tissue samples, for example of tumour cells, shall typically have a thickness of 35 nm. These thin slices are applied to a carrier and subsequently analysed in a scanning electron microscope. In this context, the thin slices are supplied to an electron detector inside the scanning electron microscope. The prepared photographs of the thin slices are stored electronically and can be processed using appropriate software in such a way that a layered computer image of the sample can be produced on the basis of a series of thin slice photographs. As a result, the sample can be considered and analysed three-dimensionally as a digital layer model.

So as to be able to supply a series of thin slices to the analysis in a scanning electron microscope, it is known to arrange thin slices on a sample holder and to deposit them in a scanning electron microscope for analysis. It is further known to provide holders in the form of a tape, the tape usually being arranged in the form of segments on a carrier plate, for example in the form of a round wafer. The wafer usually consists of a silicon monocrystal. This arrangement of thin slices on a carrier plate requires the tape to be cut apart and the tapes provided with the thin slices to be arranged manually on the carrier plate. Thus, this method is particularly complex.

The tapes known in the art are usually produced from a polyimide film. This material does have a high level of chemical resistance, but it is problematic that a tape produced from polyimide film has hydrophobic properties, meaning that the thin slices produced by the microtome do not readily adhere. It is therefore necessary to pre-treat the tape or provide it with a coating in such a way that hydrophilic properties come about. A further problem is that the material is not electrically conductive, meaning that problems with electrostatic charging of the thin slices can occur. However, electrostatic charging makes it more difficult or impossible to analyse the thin slices in a scanning electron microscope.

The object of the invention is to provide a system which offers a simple and cost-effective option for preparing thin slices and analysing them in a scanning electron microscope.

This object is achieved by the features of claims 1, 7, 16, 19 and 20. The dependent claims refer to advantageous embodiments.

According to the invention, it was found that it is advantageous to use magnetic tape for the purpose of transportation of thin slices of samples in the field of scanning electron microscopy. The advantages of using magnetic tape for transportation purposes in the field of scanning electron microscopy are described below.

The microtome for achieving the object comprises a blade for cutting thin slices from a sample, a sample holder for supplying the sample to the blade, and a means for receiving the thin slices, the thin slices being deposited on a tape which is unwound from a first holder and wound up together with the thin slices on a second holder.

The microtome according to the invention thus provides that thin slices are deposited on a tape. However, this tape is not arranged in segments on a carrier plate, but instead the tape is wound up as a whole together with the thin slices deposited thereon. As a result, it is possible to prepare thin slices and deposit them on the tape continuously. It is not necessary to split up the tape subsequently and arrange it on a carrier plate in segments strip by strip. As a result, a particularly large number of thin slices can be prepared and deposited on a single, one-piece tape. The work can be carried out continuously and without interruptions.

The tape is preferably electrically conductive and hydrophilically furnished. The electrical conductivity can prevent the thin slices from being electrostatically charged; the hydrophilic furnishing ensures that the thin slices are deposited on the tape securely and without folds and adhere thereto.

In an advantageous embodiment, the tape is provided with paramagnetic particles. The paramagnetic particles prevent accumulation of electrons on the surface of the tape and an undesired electrical charge. Due to the tape having paramagnetic as well as hydrophilic properties, it is possible to deposit samples on the tape free from creases and to wind the tape up without having to apply another tape. In this respect, it is not necessary to make a sandwich construction consisting of two tapes with in-between samples.

In tests, in this context it has surprisingly been found that a magnetic tape is extremely well suited for acting as a tape for depositing and transporting thin slices in the field of microscopy, especially scanning electron microscopy. In this context, it has been shown that a magnetic tape known from digital storage technology is extremely well suited for acting as a carrier for depositing and transporting the thin slices.

Magnetic tapes of this type consist of a film a few micrometres thick, of a thickness of approximately 4 μm to 12 μm. The film preferably consists of polyester (PE), in particular of polyethylene terephthalate (PET). A biaxially orientated polyester film of polyethylene terephthalate gains a particular high tensile strength and chemical, mechanical and thermal stability from a stretching process.

A magnetically effective layer of an iron oxide is applied to the carrier film to a thickness of 3 μm to 8 μm. In this context, however, it is also conceivable for the magnetically effective layer to consist of carbon. The material of the magnetically effective layer is provided with a binder and applied to the carrier film. This magnetically effective layer results in the advantageous electrical properties of the tape. If a partially electrically conductive thin slice is deposited on the tape and bombarded with electrons during the analysis, charge dissipation of the non-backscattered electrons remaining in the thin slice occurs. It has further been shown that the magnetic tape is hydrophilic, in such a way that thin slices are positioned on the tape excellently and free from creases by passive adhesion.

The tape may be provided with a surface coating. Magnetic tapes used for storage technology often have excessive surface irregularities, leading to the thin slices not being able to be deposited on the tape in a planar manner and in an orientation in a horizontal plane. This makes it more difficult to scan the thin slices using the scanning electron microscope. As a result of the surface coating, some surface roughnesses and irregularities are rectified, resulting in a tape having a high surface quality. In particular, a thermoplastic material may be considered as a material for the surface coating. In this context, a polymer coating can be advantageous. It may be applied to the tape in an aqueous dispersion.

The tape can be provided with a metallic coating. In an advantageous embodiment, the metallic coating comprises gold. The thickness of the metallic coating can be up to 30 nm. The metallic coating improves the electromagnetic properties of the tape and improves especially the recovery of back-scattered electrons. Furthermore, due to the metallic coating, it is possible to transport particularly thin slices of samples.

The metallic coating can be deposited on the tape via sputtering. This method allows to deposit materials having a high melting point on materials having a lower melting point.

A supply means may be provided which guides the tape to the blade. The supply means comprising a first holding on which a first spool is rotatably arranged. The tape is wound up on the first spool, and is unwound from the first spool during the preparation of thin slices. The supply means further comprises a second holder for receiving the tape provided with the samples. During the preparation of thin slices, the tape is unwound from the first spool, guided towards the blade, provided with thin slices there, guided towards the second holder and wound up there. The tape may be removed from the supply means to a scanning electron microscope for analysing the thin slices.

In an advantageous embodiment, the first spool is formed as a double-flanged spool. In this embodiment, the tape is held securely between the flanges of the spool.

The supply means may further have a direction change. The direction change is located in the direct proximity of the blade. There, the tape unwound from the first spool changes direction and is guided towards the second holder. The thin slices are deposited on the tape in the region of the direction change. In an advantageous embodiment, the direction change is a rod, preferably of high-grade steel, fastened in the supply means. The tape is thus guided around the rod.

The supply means may further have a container for receiving liquid. In this context, the container may be arranged in the microtome in such a way that the blade is also wetted at least in part with the liquid received in the container. The thin slices prepared by the blade likewise come into contact with and are wetted by the liquid.

Preferably, the tape is also passed through the liquid and wetted with liquid. Because both the thin slices and the tape are wetted with liquid, this results in excellent adhesion of the thin slices on the tape. Because the blade is wetted at least in part with liquid, the thin slices can be prevented from adhering to the blade. The preparation of thin slices in a water bath is also advantageous because the thin slices prepared for a scanning electron microscope are too thin and unstable for mechanical lifting. Therefore, the container for receiving the liquid is attached directly to the knife. The thin slices float on the surface of the meniscus and are removed, floating, from the tape from the surface.

In order for the tape also to be wettable with liquid from the container, the direction change preferably takes place in such a way that the tape is wetted with liquid before the thin slices are received. For this purpose, the direction change is preferably assigned directly to the container and fastened in the container in such a way that at least part of the direction change is located below the meniscus. This ensures that the tape is passed through the liquid and thus wetted with liquid before receiving thin slices.

The supply means preferably has a drive motor which brings about the winding and unwinding of the tape. An advantageous drive motor is an electric stepper motor. A stepper motor makes uniform transport of the tape possible. To achieve a slow feed rate, the drive motor may be provided with a transmission.

Distilled water, for example, may be considered as the liquid.

Preferably, the microtome is provided with an arrangement for generating an initial tension of the belt. The arrangement ensures that the tape is moving against a resistance, with the result that the tape is mechanically pre-stressed at all times. This is advantageous, as the arrangement is ensuring that the tape is uniformly launched and that the samples can be deposited on the tape free from creases. Preferably, the arrangement is assigned to the spool from which the tape is wound up. The arrangement is preferably formed as a torque brake. A torque brake, for example, can be formed as a gravity brake or as an eddy current brake.

A scanning electron microscope according to the invention comprising an electron detector comprises a chamber and a sample supply means, the sample supply means being formed to supply the thin slices located on the wound-up tape to the electron detector.

The sample supply means comprises a holder for receiving a second spool on which the wound-up tape having the thin slices deposited thereon is located. A holder for an empty spool, on which the tape provided with the thin slices is wound up again after being read out by the scanning electron microscope, is further located on the sample supply means.

In this context, the sample supply means is preferably formed in such a way that the thin slices arranged on the tape can be supplied to the electron detector continuously. For this purpose, the sample supply means comprises a stepper motor suitable for vacuum operation. The stepper motor is operatively connected to the empty spool, and brings about continuous unwinding of the tape from the second spool. In this context, the tape may be unwound in such a way that the unwinding is temporarily stopped when a thin slice is being scanned by the electron detector. To achieve a slow feed rate, a transmission may be assigned to the stepper motor.

The arrangement for supplying samples is preferably provided with an arrangement for generating initial tension of the belt. The arrangement ensures that the tape is moving against a resistance, with the result that the tape is mechanically pre-stressed at all times. This is advantageous, as the arrangement is ensuring a constant contact pressure of the tape on the plateau which is arranged directly underneath the electron lense. The constant contact pressure is adding to having a constant operating distance between the sample and the electron lense. Preferably, the arrangement is assigned to the spool from which the tape is wound up. The arrangement is preferably formed as a torque brake. A torque brake, for example, can be formed as a gravity brake or as an eddy current brake.

The arrangement according to the invention of the scanning electron microscope makes it possible to supply thin slices in a particularly rapid and simple manner. In particular, the intermediate step of splitting up the thin slices deposited on the tape into segments and arranging them on a carrier plate is omitted.

In the arrangement according to the invention, the tape provided with the thin slices is wound up and supplied to the scanning electron microscope in roll form. There, the wound-up tape is unwound by the sample supply means and wound up again after being read out by the scanning electron microscope, in such a way that the thin slices are made available to the electron detector for reading out.

In the method for preparing thin slices using a microtome, in a first step a sample is supplied to a blade which cuts off thin slices from the sample, and in a second step the thin slices are deposited on a tape which is unwound from a first spool and wound up together with the thin slices on a second holder.

In a method according to the invention for analysing thin slices in a scanning electron microscope, a tape provided with thin slices and wound up is unwound and wound up again by means of a sample supply means, the thin slices deposited on the tape being supplied to the electron detector between the unwinding and the winding.

Some embodiments of the microtome and the scanning electron microscope according to the invention are described in greater detail in the following. The drawings show in each case schematically:

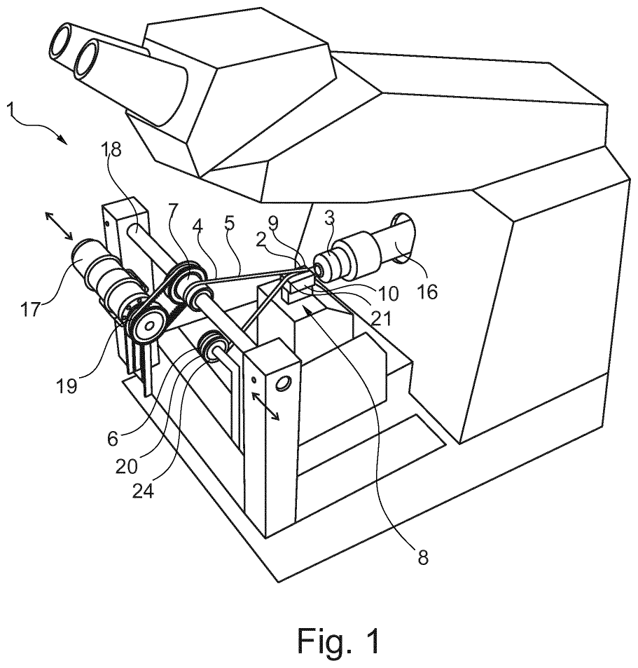

FIG. 1 is a three-dimensional drawing of a microtome;

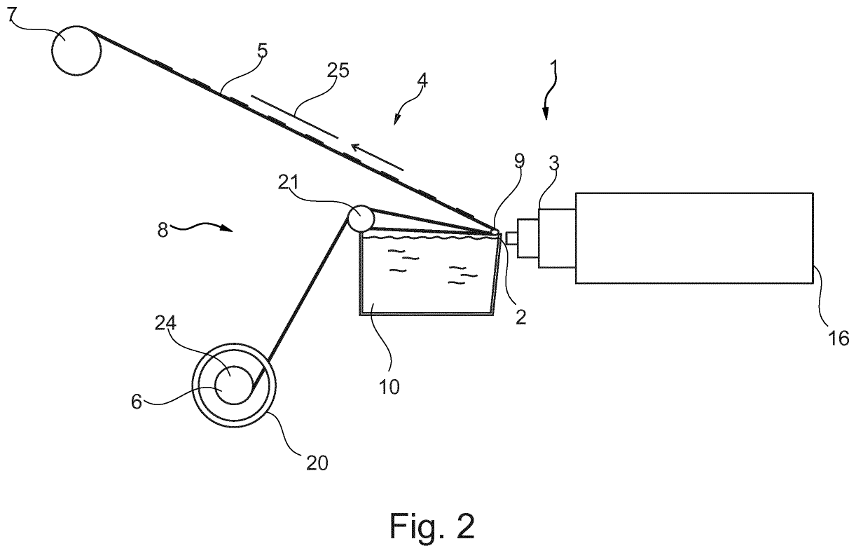

FIG. 2 shows the supply means in detail;

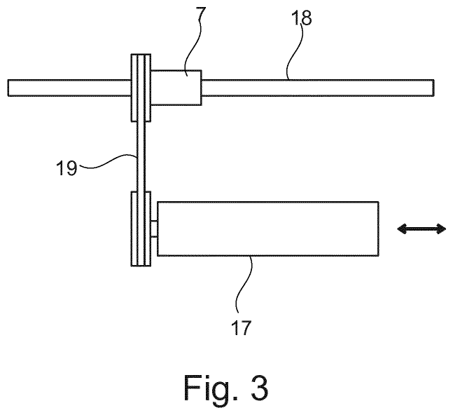

FIG. 3 shows the drive of the second holder in detail;

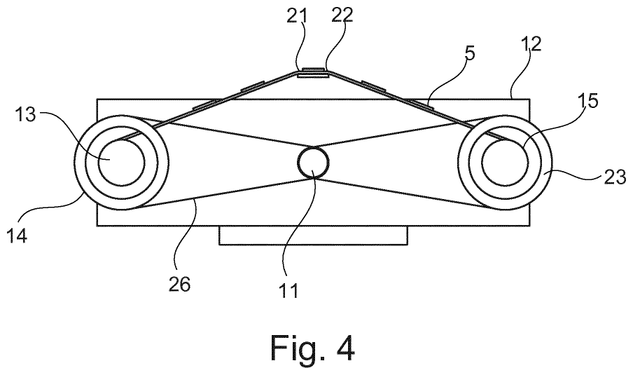

FIG. 4 is a front view of a sample supply means;

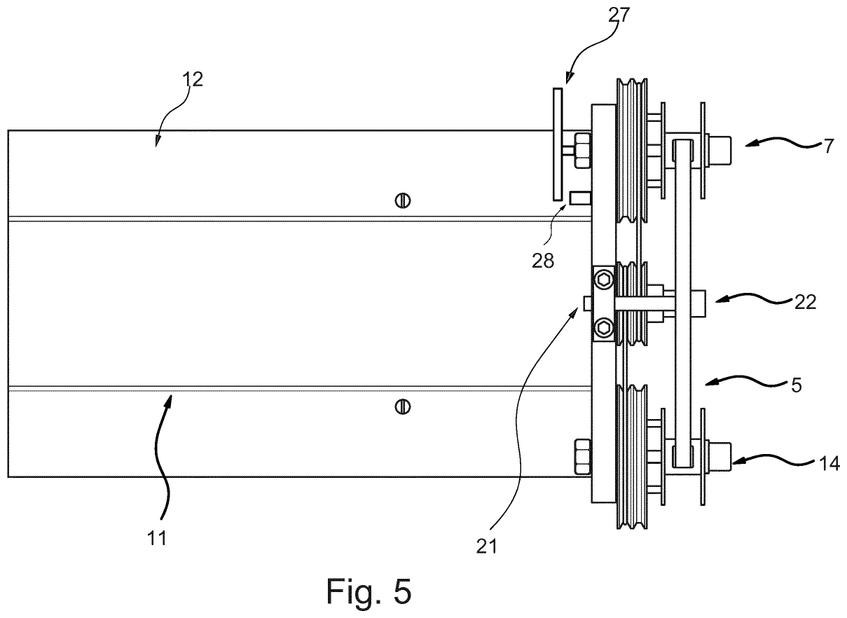

FIG. 5 is a plan view of a sample supply means;

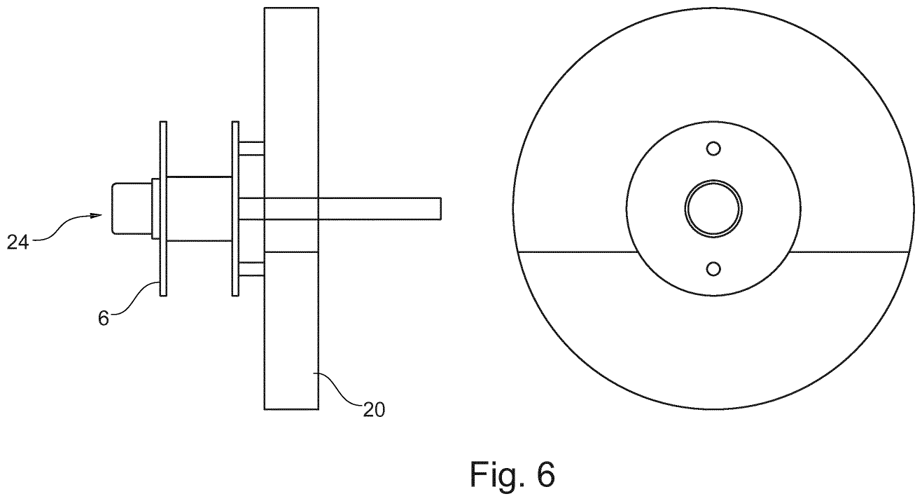

FIG. 6 shows in detail the torque brake for the first holder;

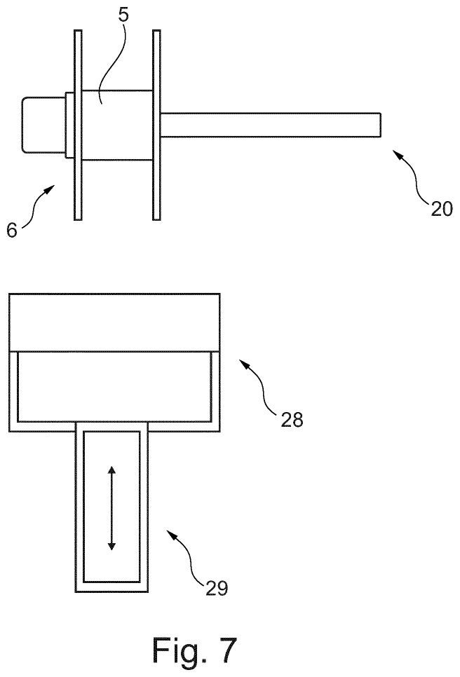

FIG. 7 shows in detail an alternative torque brake.

FIG. 1 shows a microtome 1 suitable for preparing thin slices and ultrathin slices of samples having a thickness of approximately 35 nm. In this context, the microtome 1 is in particular suitable for splitting up samples in the form of tissue samples which have previously been stabilised, for example, using epoxy resin.

The microtome 1 comprises a blade 2 in the form of a diamond knife for cutting thin slices from a sample, a sample holder 3 for supplying the sample to the blade 2, and a means 4 for receiving the thin slices, the means 4 being a tape 5 on which the thin slices are deposited. In the present embodiment, the sample holder 3 along with the sample fastened thereon is moved in translation by means of an electric motor 16, the sample sliding along on the blade 2 and thin slices being cut off from the sample.

The tape 5 is a continuous tape which is unwound from a first spool 6 attached to a first holder 24 and wound up together with the thin slices on a second holder 7. The tape 5 is electrically conductive and hydrophilically furnished, the tape 5 in the present case being formed from a magnetic tape. In this context, a magnetic tape having a thickness of 16 μm known from digital storage technology is used. The magnetic tape comprises a carrier film of polyethylene terephthalate. A magnetically effective layer of iron oxide, which is provided with a binder, is applied to the carrier film to a thickness of 5 μm. To improve the surface consistency, the tape 5 is provided with a surface coating.

The surface coating improves the surface quality of the tape 5. Further, the surface coating also improves the hydrophilic properties of the tape 5. A particularly advantageous surface coating comprises a thermoplastic plastics material. A polymer coating has been found to be particularly advantageous. Another advantageous surface coating comprises a metallic material, especially in the form of a gold coating. The metallic coating is advantageously applied via sputtering.

FIG. 2 shows in detail the supply means 8 disclosed in FIG. 1, which guides the tape 5 to the diamond knife of the blade 2. In this context, the supply means 8 has a direction change 9 in the form of a high-grade steel rod. In the present case, the direction change 9 has a diameter of 1 mm. The supply means 8 further comprises a container 10 for receiving liquid, the tape 5 changing direction in such a way that the tape 5 is wetted with liquid before receiving thin slices. The blade 2 is likewise assigned to the container 10. After cutting, the thin slices are initially transported on the meniscus and finally removed from the tape 5. In this context, both the thin slices and the tape 5 are wetted with liquid. A further direction change 21 causes the tape 5 to change direction in such a way that the tape 5 is guided via the container and wetted with liquid in the region of the direction change 9.

A heating means 25 for drying the thin slices deposited on the tape 5 is assigned to the supply means 8. In an advantageous embodiment, the heating means 25 comprises a Peltier element, which is heated in parts by applying an electrical voltage. The thermal radiation produced as a result is sufficient to dry the thin slices and the tape 5 prior to winding up. In this context, it is also advantageous that higher process speeds are possible.

In the method for preparing thin slices using a microtome 1, in a first step a sample is supplied to a blade 2 which cuts off thin slices from the sample, and in a second step the thin slices are deposited on a tape 5 which is unwound from a first spool 6 and wound up together with the thin slices on a second holder 7.

The first spool 6 is provided with a torque brake 20 in the form of an eddy current brake (FIG. 7). Alternatively, the first spool can be provided with a torque brake 20 in the form of a disc filled with liquid (FIG. 6).

Further, it is conceivable to provide initial tension of the tape by modification of the turning resistance, for example by clamping of the bearings.

FIG. 3 shows in detail the drive disclosed in FIG. 1, which winds the tape 5 from the first spool 6 onto the second holder 7. The second holder 7 is operatively connected to a stepper motor 17. Both the first spool 6 and the second holder 7 are rotatably arranged on a shaft 18, the stepper motor 17 being connected to the second holder 7. The stepper motor 17 acts on the second holder 7 directly via a toothed belt drive 19. This ensures that the tape 5 is wound onto the second holder 7 uniformly and continuously. A high-ratio transmission is assigned to the stepper motor 17. In the present embodiment, this ratio is 2,070:1.

In the present embodiment, the shaft 18 on which the second holder 7 is arranged is rigidly fastened in the supply means 8, and the second holder 7 is rotatably mounted on the shaft 18. In this embodiment, the toothed belt drive 19 is assigned to the second holder 7 and also rotatably mounted on the shaft 18.

In the present embodiment, the stepper motor 17 is mounted in the supply means 8 in such a way that said motor can be displaced parallel to the axis. Together with the stepper motor 17, the first holder 24 comprising the first spool 6 and the second holder 7 may also be displaced parallel to the axis. As a result, the position of the tape 5 relative to the blade 2 can be displaced in such a way that the tape 5 is always optimally positioned to receive the samples.

The arrangement comprising the first spool 6, the second holder 7, the supply means 8, the direction change 9, the stepper motor 17, the shaft 18, the torque brake 20 and the first holder 24 is rigidly connected to the microtome 1. Thus, the direction change 9 is firmly assigned to the blade 2. This ensures a constant distance independently from external influences between the direction change 9, with the tape 5 redirected on it, and the blade 2.

FIGS. 4 and 5 show a sample supply means 12 which can be arranged in the vacuum chamber of a scanning electron microscope. In this context, the sample supply means 12 is formed to supply the thin slices located on the wound-up tape 5 on the second holder 7 to the electron detector. In this context, the slices are supplied continuously.

The sample supply means 12 has a first retainer 13 for an empty spool 14 and a second retainer 15 for a second spool 23. The tape 5 provided with the samples is located on the second spool 23. For this purpose, in an intermediate step, the tape 5 may be wound up from the second holder 7 onto the second spool 23.

The second retainer 15 is provided with a metal disc 27 which is operatively connected to a permanent magnet 28. When the second spool 23 is rotating, the permanent magnet 28 induces an eddy current inside of the metal disc 27. Due to the ohmic resistance, part of the yielded energy is transformed into heat. Thus, the permanent magnet 28 and the metal disc 27 form a torque brake, more precisely an eddy current brake. The result is a resistance against rotation of the second spool 23 which then again results in an initial tension of the tape 5 so that the tape can be unwound uniformly. The distance between the permanent magnet 28 and metal disc 27 may be adjustable.

The empty spool 14 is operatively connected to a second electric motor 11 so as to wind the tape 5 from the second spool 23 onto the empty spool 14 and thus to supply the thin slices to the electron detector. The second electric motor 11 is provided with a high-ratio transmission. In the present case, the ratio is 2,070:1. Further, the second electric motor 11 is furnished for operation in a vacuum. The force transmission from the second electric motor 11 to the empty spool 14 takes place by way of a traction mechanism drive; in this case by means of a second toothed belt drive 26.

The sample supply means 12 is configured in such a way that the thin slices arranged on the tape 5 can be supplied to the electron detector of the scanning electron microscope continuously. For this purpose, the sample supply means 12 comprises a second electric motor 11 suitable for vacuum operation in the form of a stepper motor. The second electric motor 11 is operatively connected to the empty spool 14, and brings about continuous unwinding of the tape 5 from the second spool 23. A second direction change 21 is arranged between the second spool 23 and the empty spool 14. The tape 5 is guided via the second direction change 21, the second direction change 21 having a plateau 22, the scanning by the electron detector taking place on the plateau 22. The plateau is formed by a horizontally orientated support made of a polished wafer.

The sample supply means 12 is fastened in the scanning electron microscope by means of a fastening element.

In this context, the tape 5 may be unwound in such a way that the second electric motor 11 temporarily stops when a thin slice or sample is being scanned on the plateau 22 by the electron detector.

In the method for analysing thin slices in a scanning electron microscope, a tape 5 provided with thin slices and wound-up is unwound and wound up on an empty spool 14 by means of a sample supply means 12, the thin slices deposited on the tape 5 being supplied to the electron detector during the unwinding from the second spool 23 and the winding onto the empty spool 14.

The spools 6, 14, 23 are formed as double-flanged spools.

FIG. 6 shows in detail the first spool 6 which is provided with a torque brake 20. In order for the tape 5 also to be able to be unwound uniformly from the first spool 6, a torque brake 20, which is rotationally engaged with the first holder 24 or the first spool 6, is arranged on the shaft on which the first spool 6 is mounted.

In an advantageous embodiment, the torque brake 20 consists of a disc which is fastened to the shaft and provided with an annular cavity. The cavity is filled at least in part with a liquid, in the present case with a mixture of water and glycerol.

If the torque brake 20 is set in rotation together with the first spool 6, the disc moves, whilst the liquid remains in place. This results in a slight friction of the liquid on the inner wall of the cavity and a constant restoring force, leading to a constant slight resistance to the rotational movement. This resistance is sufficient for the tape 5 to have a small bias and be unwound uniformly from the first spool 6. As a result of the liquid/solid tribological pairing, there is also no stick-slip effect, which would lead to a jerky movement of the tape 5. As a result of the arrangement of the torque brake 20, a uniform tensile stress of the tape 5 is always provided, leading to uniform unwinding and winding of the tape 5. Such a torque brake 20 can be referred to as a gravity torque. Against the background of low torques needed for moving of the tape, the torque brake is particularly advantageous as it is generating a low and consistent torque.

FIG. 7 depicts an alternative embodiment of a torque brake. In this embodiment, the first spool 6 is made of electrically conductive material. A magnet 28, here a permanent magnet 28, is assigned to the first spool 6, the permanent magnet 28 being attached adjustably on the microtome 1 relative to the first spool 6. The adjustment of the permanent magnet 28 is realized by a height adjustment 29 on which the permanent magnet 28 is arranged. When the first spool 6 is rotating, the permanent magnet 28 induces an eddy current inside of the electrically conductive sections of the first spool 6. Due to the ohmic resistance, part of the yielded energy is transformed into heat. Hence, the result is a resistance against rotation of the first spool 6 which then again results in an initial tension of the tape 5. The closer the permanent magnet 28 is positioned on the first spool 6, the greater the resistance. In an alternative embodiment, the permanent magnet 28 can be formed as an electromagnet.

What is claimed is:

1. A magnetic tape used for the purpose of depositing and transporting of thin slices of samples in the field of scanning electron microscopy.

2. The magnetic tape according to claim 1 used for the purpose of depositing and transporting of thin slices of samples while cutting the slices with a microtome.

3. The magnetic tape according to claim 1 used for the purpose of depositing and transporting of thin slices of sampled while analysing the slices in a scanning electron microscope.

4. The magnetic tape according to claim 1, wherein the tape is electrically conductive and hydrophilically furnished.

5. The magnetic tape according to claim 1, wherein the tape is provided with a surface coating.

6. The magnetic tape according to claim 5, wherein the surface coating is a metallic coating.

7. A microtome, comprising a blade for cutting thin slices from a sample, a sample holder for guiding the sample onto the blade, and a means for receiving the thin slices, the means being a tape on which the thin slices are deposited, wherein the tape is unwound from a first holder and wound up together with the thin slices onto a second holder.

8. The microtome according to claim 7, wherein the tape is electrically conductive and hydrophilically furnished.

9. The microtome according to claim 7, wherein the tape is formed from a magnetic tape.

10. The microtome according to claim 7, wherein the tape is provided with a surface coating.

11. The microtome according to claim 7, wherein a supply means is provided which guides the tape to the blade.

12. The microtome according to claim 11, wherein the supply means comprises a direction change.

13. The microtome according to claim 11, wherein the supply means comprises a container for receiving liquid.

14. The microtome according to claim 13, wherein the direction change takes place in such a way that the tape is wetted with liquid before receiving thin slices.

15. The microtome according to claim 7, wherein an arrangement for generating an initial tension of the tape is provided.

16. A scanning electron microscope having an electron detector, comprising a chamber and a sample supply means, wherein the sample supply means is formed to supply the thin slices located on the wound-up tape to the electron detector.

17. The scanning electron microscope according to claim 16, wherein the sample supply means is formed to supply the thin slices arranged on the tape to the electron detector continuously.

18. The scanning electron microscope according to claim 16, wherein the sample supply means has a first retainer for an empty spool and a second retainer for the second spool, the empty spool being operatively connected to a second electric motor so as to set the spools in rotation and to wind the tape from the second spool onto the empty spool and thus to supply the thin slices to the electron detector.

19. A method for preparing thin slices using a microtome, in a first step a sample being supplied to a blade which cuts off thin slices from the sample, and in a second step the thin slices being deposited on a tape which is unwound from a first spool and wound up together with the thin layers on a second holder.

20. A method for analysing thin slices in a scanning electron microscope, wherein a tape, provided with thin slices and wound-up, is unwound from a second spool and wound up onto an empty spool by means of a sample supply means, the thin slices deposited on the tape being supplied to the electron detector during the unwinding from the second spool and the winding onto the empty spool.
